(19) United States
(12) Patent Application Publication
(10) Pub. No.: US 2022/0278217 A1
(43) Pub. Date: Sep. 1, 2022

(54) HIGH DIELECTRIC CONSTANT METAL GATE MOS TRANSISTOR AND METHOD FOR MAKING THE SAME

(71) Applicant: Shanghai Huali Integrated Circuit Corporation, Shanghai (CN)

(72) Inventor: Yong Li, Shanghai (CN)

(21) Appl. No.: 17/675,809

(22) Filed: Feb. 18, 2022

(30) Foreign Application Priority Data
Mar. 1, 2021 (CN) 202110226519.1

(51) Int. Cl. H01L 29/423; H01L 29/78; H01L 29/66

(52) U.S. Cl. CPC H01L 29/42364; H01L 29/785; H01L 29/6681

(57) ABSTRACT

The present application discloses a high dielectric-constant metal gate MOS transistor and a method for making the same. The gate structure is formed by stacking a gate dielectric layer and a metal gate; the top surface of the metal gate is arranged to be lower than the top surface of the zeroth interlayer film, and a first groove is formed on the top surface of the metal gate; a gate top plug formed by stacking a first barrier layer and a first oxide layer is formed in the first groove, the first barrier layer is arranged on the bottom surface and the side surfaces of the first groove, and the first oxide layer fully fills the first groove; and the first barrier layer is made of a material that blocks oxygen ions or fluorine ions from diffusing into the high dielectric-constant layer of the gate structure.

### CROSS-REFERENCES TO RELATED APPLICATIONS

This application claims the priority to Chinese patent application No. CN202110226519.1, filed on Mar. 1, 2021, and entitled “HIGH DIELECTRIC CONSTANT METAL GATE MOS TRANSISTOR AND METHOD FOR MAKING THE SAME”, the disclosure of which is incorporated herein by reference in its entirety.

### TECHNICAL FIELD

The present application relates to the field of semiconductor integrated circuit manufacturing, in particular, to high dielectric-constant metal gate (HKMG) MOS transistors and methods for manufacturing the same.

### BACKGROUND

In the continuous development of the semiconductor technology, HKMG as gate structures of MOS transistors has shown excellent performance. A gate dielectric layer in the HKMG includes a high dielectric-constant layer. The high dielectric-constant layer generally contains a material with a dielectric-constant higher than that of silicon dioxide, such as hafnium dioxide or zirconium dioxide, wherein the hafnium dioxide is a relatively common high dielectric-constant material. The metal hafnium (Hf) or the metal zirconium (Zr) has the monoclinic crystal structure, so it is easy for Hf or Zr to form 3 covalent bonds or 4 covalent bonds when combined with oxygen (O). Therefore, materials containing Hf or Zr, such as hafnium dioxide or zirconium dioxide, contain oxygen vacancies (Vo++), and the oxygen vacancies may form oxygen diffusion channels, through which oxygen or fluorine ions diffuse easily into the high dielectric-constant layer where they are combined with the oxygen vacancies, which eventually affects the threshold voltage (Vt) of the device containing them, such as causing a Vt mismatch (VTMM) of the device.

In order to prevent the combination of oxygen vacancies in the high dielectric-constant layer and diffused oxygen or fluoride ions, which imposes an adverse impact on the threshold voltage of the device, a gate top plug has been introduced into the top of the gate structure. The gate top plug can prevent oxygen or fluorine ions from diffusing downwards from the top of the gate structure into the high dielectric-constant layer. The gate top plug in this existing method is formed by filling a groove formed by etch-back of the top of the gate structure with silicon nitride, as shown in the following description:

FIGS. 1A-1D are schematic structure diagrams of the high dielectric-constant metal gate MOS transistor device during the existing manufacturing method steps. The existing method for manufacturing a high dielectric-constant metal gate MOS transistor includes the following steps:

Step 1: referring to FIG. 1A, a zeroth interlayer film 106 and a gate structure are formed on the surface of a semiconductor substrate 101.

The gate structure is formed by stacking a gate dielectric layer and a metal gate, and the gate dielectric layer includes a high dielectric-constant layer 1022.

Chemical mechanical planarization is performed on the metal gate structure so that the top surface of the metal gate is flush with the top surface of the zeroth interlayer film 106.

In FIG. 1A, a formation area of the gate structure is shown in the dashed line box 102. The gate structure is generally formed by means of a gate last process. The gate last process is a common technique in this field and is briefly described as follows:

The gate structure formation area is defined by a dummy gate structure, then the gate structure is formed in an area where the dummy gate structure is removed.

The dummy gate structure is formed before the gate structure is formed, and the dummy gate structure is generally formed by stacking a gate oxide layer and a dummy polysilicon gate.

Then, a sidewall 103 is formed on the side surfaces of the dummy gate structure in the manner of self-alignment.

Then, a source area 104a and a drain area 104b are formed at the side surfaces of the sidewalls 103 of the dummy gate structure by means of heavily-doping source and drain via ion implantation in the manner of self-alignment.

Then, a contact etch stop layer 105 is formed, wherein the contact etch stop layer 105 covers the top surface of the dummy gate structure, the side surfaces of the sidewalls, and the remaining surface of the semiconductor substrate 101 outside the sidewalls.

Next, the zeroth interlayer film 106 is formed, wherein the zeroth interlayer film 106 covers the surface of the contact etch stop layer 105.

An etch-back or chemical mechanical planarization process is performed to remove the zeroth interlayer film 106 and the contact etch stop layer 105 on the top surface of the dummy gate structure, thereby the top surfaces of the zeroth interlayer film 106 and the contact etch stop layer 105 outside the dummy gate structure are flush with the top surface of the dummy gate structure. The top surface of the dummy gate structure is then exposed.

Next, the dummy gate structure is removed.

As the result, the gate structure is formed.

Generally, the gate dielectric layer of the gate structure includes an interface layer 1021, a high dielectric-constant layer 1022, and a bottom barrier metal layer 1023 that are sequentially stacked up; and the metal gate of the gate structure also includes a work function layer 1024, a top barrier metal 1025, and a metal conductive material layer 1026 that are also sequentially stacked up.

If the high dielectric-constant metal gate MOS transistor is an N-type device, the work function layer 1024 is an N-type work function layer; and if the high dielectric-constant metal gate MOS transistor is a P-type device, the work function layer 1024 is a P-type work function layer.

The material of the interface layer 1021 includes silicon oxide.

The material of the high dielectric-constant layer 1022 includes one or a combination of silicon nitride, aluminum sesquioxide, tantalum pentoxide, yttrium oxide, hafnium silicate, hafnium dioxide, lanthanum oxide, zirconium dioxide, strontium titanate, and zirconium silicate.

The bottom barrier metal 1023 includes a stacked layer of a titanium nitride layer and a tantalum nitride layer.

The material of the top barrier metal 1025 is titanium nitride (TiN) or a stacked layer of TiN and Ti.

The material of the N-type work function layer includes titanium aluminide (TiAl), titanium aluminium carbide (TiAlC), titanium aluminium nitride (TiALN); and the material of the P-type work function layer includes TiN.

Generally, the semiconductor substrate 101 includes a silicon substrate.

As the size of the process node decreases continuously, a fin structured transistor is constructed into a high dielectric-constant metal gate MOS transistor. In FIG. 1A, a fin 101a is formed on the semiconductor substrate 101, the fin 101a is made of the material of the semiconductor substrate 101, and the positions of the top surface and side surfaces of the fin 101a are above the surface of the semiconductor substrate 101 outside the fin 101a.

The high dielectric-constant metal gate MOS transistor is formed on the fin 101a.

In the formation area of the gate structure, the gate structure covers the top surface and the side surfaces of the fin 101a. It can be seen that, compared with a planar transistor, the fin transistor has a three-dimensional structure, in which a conductive channel is formed on both the top surface and the side surfaces of the fin 101a, increasing the width of the conductive channel, and thereby improving the performance of the device.

The source area 104a and the drain area 104b are formed in the fin 101a on two sides of the gate structure.

Step 2: referring to FIG. 1B, the metal gate is etched back so that the top surface of the metal gate is lower than the top surface of the zeroth layer interlayer film 106, and a first groove 107 is formed on the top surface of the metal gate, wherein the top surface of opening of the first groove 107 is flush with the top surface of the zeroth interlayer film 106.

Step 3: referring to FIG. 1C, a silicon nitride layer 108a is disposed into the first groove 107 and covers its bottom surface and the side surfaces, wherein the silicon nitride layer 108a is generally formed by means of a chemical vapor deposition process, so the silicon nitride layer 108a extends to the surface of the zeroth interlayer film 106 outside the first groove 107.

Step 4: referring to FIG. 1D, a chemical mechanical planarization process is performed to remove the silicon nitride layer 108a outside the first groove 107 and to make the top surface of the silicon nitride layer 108 in the first groove 107 flush with the top surface of the first groove 107. In FIG. 1D, after the chemical mechanical planarization process, only the silicon nitride layer filling the first groove 107 is independently labeled with a reference number 108, and a gate top plug is thus formed by the silicon nitride layer filling the first groove 107. The gate top plug prevents oxygen atoms or fluorine atoms from diffusing into the high dielectric-constant layer 1022 of the gate structure.

The existing method further includes the following steps:

Referring to FIG. 1E, a first interlayer film 109 is formed, wherein the first interlayer film 109 covers the surfaces of the zeroth interlayer film 106 and of the gate top plug.

Referring to FIG. 1F, a zeroth metal layer (MO) is formed, wherein the zeroth metal layer includes a zeroth metal active layer (MOAA), and the zeroth metal active layer penetrating through the first interlayer film 109 and the zeroth interlayer film 106 is respectively formed on top of each of the source area 104a and the drain area 104b. In FIG. 1F, the zeroth metal active layer on the top of the source area 104a is independently labeled with a reference number 110a, and the zeroth metal active layer on the top of the drain area 104b is independently labeled with a reference number 110b.

Then, subsequent formation processes of an interlayer film and a contact are performed until all back-end-of-line (BEOL) processes are completed. The subsequent process is the same as the standard process and is not described in detail herein. In a lead-out area (not shown in the section corresponding to FIG. 1F) of the gate structure, an opening of the contact that penetrates through the silicon nitride layer 108 is formed on the top of the metal gate.

In the existing method, by introducing the gate top plug formed by the silicon nitride layer 108, oxygen or fluorine ions can be prevented from diffusing into the high dielectric-constant layer, thereby preventing the combination of the oxygen or fluorine ions with oxygen vacancies in the high dielectric-constant layer which imposes an adverse impact on the threshold voltage of the device. In addition, the addition of the gate top plug can reduce the gate-drain capacitance (Cgd), thereby improving the alternating current performance of the device. The performance of isolation between the zeroth metal active layers 110a and 110b each from the gate structure can also be improved.

However, during continuous reduction of the semiconductor feature dimensions when the process node moves to smaller nanometers, such as the node of less than 7 nm, the width of the gate structure is reduced to less than 20 nm, in which case a void can be often produced during filling the first groove 107 with the silicon nitride layer 108a. After the chemical mechanical planarization process corresponding to FIG. 1D, typically some voids still remain in the silicon nitride layer 108, and these remaining voids will deteriorate the performance of the device. In addition, when the contact is formed on top of the metal gate of the gate structure, the opening of the contact passes through the silicon nitride layer 108, the voids in the silicon nitride layer 108 exert a destructive effect during etching of the opening of the contact, which is not conducive to the prevention of oxygen or fluoride ions from diffusing downwards from the top of the gate structure into the high dielectric-constant layer, imposing an adverse impact on the threshold voltage of the device. For example, the threshold voltage mismatch increases and the stability of the threshold voltage deteriorates. This problem needs to be solved in order to provide a high dielectric-constant metal gate MOS transistor with improved alternating current performance, without the threshold voltage mismatch in the device.

### BRIEF SUMMARY

In view of the above, the present application provides a high dielectric-constant metal gate MOS transistor and a method for manufacturing it.

The present application discloses a high dielectric-constant metal gate MOS transistor y, a zeroth interlayer film, and a gate structure formed on a surface of a semiconductor substrate.

The gate structure is formed by stacking a gate dielectric layer and a metal gate, and the gate dielectric layer comprises a high dielectric-constant layer.

The top surface of the metal gate is configured to be lower than the top surface of the zeroth interlayer film, a first groove is formed on the top surface of the metal gate, and the top surface of the first groove is configured to be flush with the top surface of the zeroth interlayer film.

A gate top plug formed by stacking a first barrier layer and a first oxide layer is formed in the first groove, the first barrier layer is arranged on the bottom surface and the side surfaces of the first groove, and the first oxide layer is configured to fill the first groove.

The first barrier layer is made of a material that can prevent oxygen ions or fluorine ions from diffusing into the high dielectric-constant layer of the gate structure.

In a further improvement, the first barrier layer extends to the surface of the zeroth interlayer film outside the first groove.

In a further improvement, the material of the first barrier layer is selected from one of SiN, SiON, SiC, SiCN, SiCBN, SiOBN, Al₂O₃, and ZrO₂, or the first barrier layer is formed by stacking more than two layers each selected from one of SiN, SiON, SiC, SiCN, SiCBN, SiCOBN, Al₂O₃, and ZrO₂.

In a further improvement, the semiconductor substrate comprises a silicon substrate.

In a further improvement, the high dielectric-constant metal gate MOS transistor is a fin transistor; a fin is formed on the semiconductor substrate, the fin is made of the material of the semiconductor substrate, and the top surface and the side surfaces of the fin are arranged on the surface of the semiconductor substrate outside the fin.

The high dielectric-constant metal gate MOS transistor is formed on the fin.

In a formation area of the gate structure, the gate structure covers the top surface and the side surfaces of the fin.

A source area and a drain area are formed in the fin on two sides of the gate structure.

In a further improvement, a first interlayer film covers the surfaces of the zeroth interlayer film and the gate top plug.

In a further improvement, the first oxide layer is directly composed of the first interlayer film filling the first groove.

In a further improvement, a zeroth metal active layer penetrating through the first interlayer film and the zeroth interlayer film is formed on top of each of the source area and the drain area.

The method for manufacturing a high dielectric-constant metal gate MOS transistor provided by the present application comprises the following steps:

step 1: forming a zeroth interlayer film and a gate structure on the surface of a semiconductor substrate,

wherein the gate structure is formed by stacking a gate dielectric layer and a metal gate, and the gate dielectric layer comprises a high dielectric-constant layer, and

chemical mechanical planarization is performed on the metal gate so that the top surface of the metal gate is flush with the top surface of the zeroth interlayer film;

step 2: etching back the metal gate so that the top surface of the metal gate is lower than the top surface of the zeroth interlayer film, and forming a first groove on the top surface of the metal gate, wherein the top surface of the first groove is flush with the top surface of the zeroth interlayer film;

step 3: forming a first barrier layer on the bottom surface and the side surfaces of the first groove, wherein the first barrier layer is made of a material that can prevent oxygen ions or fluorine ions from diffusing into the high dielectric-constant layer of the gate structure; and

Step 4: filling the first groove with a first oxide layer, and forming a gate top plug by stacking the first barrier layer and the first oxide layer.

In a further improvement, the first barrier layer extends to the surface of the zeroth interlayer film outside the first groove.

In a further improvement, the first barrier layer includes materials selected from one of SiN, SiON, SiC, SiCN, SiCBN, SiOBN, Al₂O₃, and ZrO₂, or the first barrier layer may also include stacked more than two layers each selected from one of SiN, SiON, SiC, SiCN, SiCBN, SiCOBN, Al₂O₃, and ZrO₂.

In a further improvement, the semiconductor substrate comprises a silicon substrate.

In a further improvement, the high dielectric-constant metal gate MOS transistor is a fin transistor; a fin is formed on the semiconductor substrate, the fin is made of the material of the semiconductor substrate, and the top surface and the side surfaces of the fin are arranged on the surface of the semiconductor substrate outside the fin.

The high dielectric-constant metal gate MOS transistor is formed on the fin.

In a formation area of the gate structure, the gate structure covers the top surface and the side surfaces of the fin.

A source area and a drain area are formed in the fin on two sides of the gate structure.

In a further improvement, the method further comprises a step of:

forming a first interlayer film, wherein the first interlayer film covers the surfaces of the zeroth interlayer film and the gate top plug.

In a further improvement, the first oxide layer serves as a portion of the first interlayer film, the first oxide layer is directly composed of the first interlayer film filling the first groove, and step 4 is merged with the step of forming the first interlayer film.

In a further improvement, the method further comprises a step of:

forming a zeroth metal layer, wherein the zeroth metal layer comprises a zeroth metal active layer, and the zeroth metal active layer penetrating through the first interlayer film and the zeroth interlayer film is formed on the top of each of the source area and the drain area.

Unlike a gate top plug of a high dielectric-constant metal gate MOS transistor that is formed by filling with a silicon nitride material in the currently, the gate top plug in the present application has a filling structure formed by stacking the first barrier layer and the first oxide layer to insert into the first groove. In the stacked structure, the provision of the first barrier layer can prevent oxygen ions or fluorine ions from diffusing into the high dielectric-constant layer of the gate structure, thereby reducing the threshold voltage mismatch of the device; and because the dielectric-constant of the first oxide layer is lower than that of the silicon nitride, the gate-drain capacitance can be reduced, thereby improving the alternating current performance of the device.

In addition, in the present application, the performance of the first oxide layer in filling the first groove is better than that of silicon nitride, so voids in the filling layer can be reduced and the filling quality is improved, meeting the requirement from the continuous shrink of the device size in process node targets. For example, when the process node is reduced to less than 7 nm, the length (Lg) of the gate is reduced to 20 nm, in which case voids are easily produced during filling the first groove with the silicon nitride. However, in the present application, the voids are mitigated by filling the first groove with the first barrier layer and the first oxide layer.

Moreover, since the materials of the first oxide layer and the first interlayer film in the present application both are oxide films, the first oxide layer can be directly composed of the first interlayer film filling the first groove; therefore, in the present application, one chemical mechanical planarization process can be saved, thereby saving the manufacturing cost. In making the existing structure as filling the first groove with silicon nitride, large numbers of voids can stay in the first groove after the chemical mechanical planarization process, thereby deteriorating the performance of the device. In addition to cost saving, in the present application, the performance of the device can be improved by reducing the voids.

Furthermore, since a contact on the top of the metal gate penetrates through the gate top plug and the voids of the gate top plug of the present application are reduced, etching of an opening of the contact causes no damage to the gate top plug, thereby further reducing the threshold voltage mismatch of the device and improving the stability of the threshold voltage of the device. However, in the existing gate top plug formed by filling with silicon nitride, the etching of the opening of the contact on the top of the metal gate causes damage to the gate top plug, thereby affecting the threshold voltage mismatch performance and threshold voltage stability of the device.

In the present application, the performance of isolation between the gate structure and the zeroth metal active layer on the top of each of the source area and the drain area can be improved, thereby improving the product yield. For example, the yield of SRAMs or logic circuits adopting the high dielectric-constant metal gate MOS transistor of the present application can be improved.

### BRIEF DESCRIPTION OF THE DRAWINGS

The present application will be further described in detail below with reference to the drawings and specific implementations:

FIGS. 1A-1F are schematic structure diagrams of the high dielectric-constant metal gate MOS transistor device during the existing manufacturing method steps.

FIG. 2 is a schematic structural diagram of a high dielectric-constant metal gate MOS transistor according to an embodiment of the present application.

FIGS. 3A-3D are schematic diagrams of device structures in steps of the method for manufacturing the high dielectric-constant metal gate MOS transistors according to an embodiment of the present application.

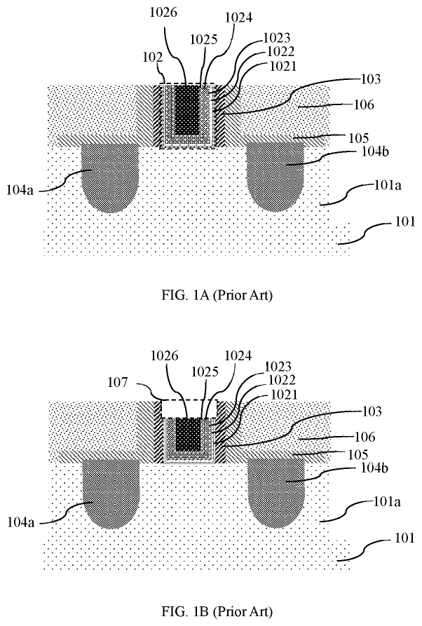

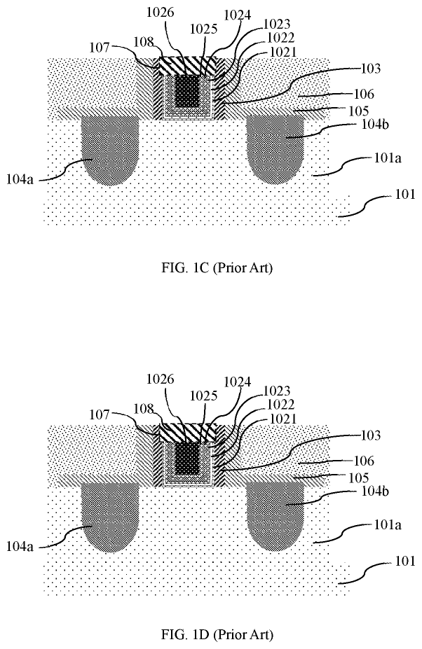

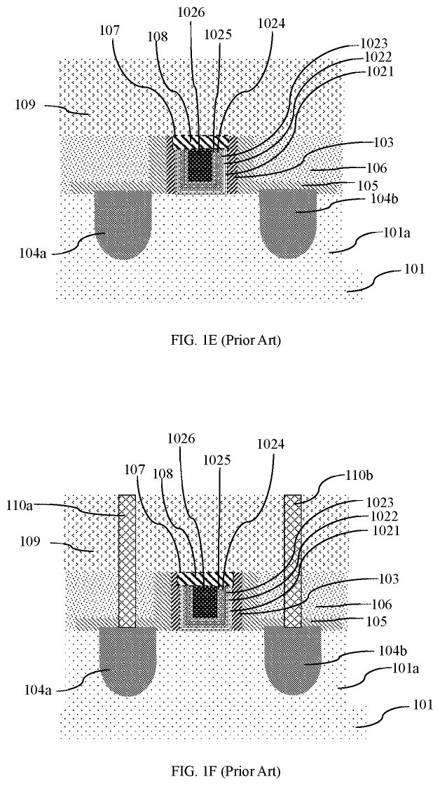

### DETAILED DESCRIPTION OF THE DISCLOSURE

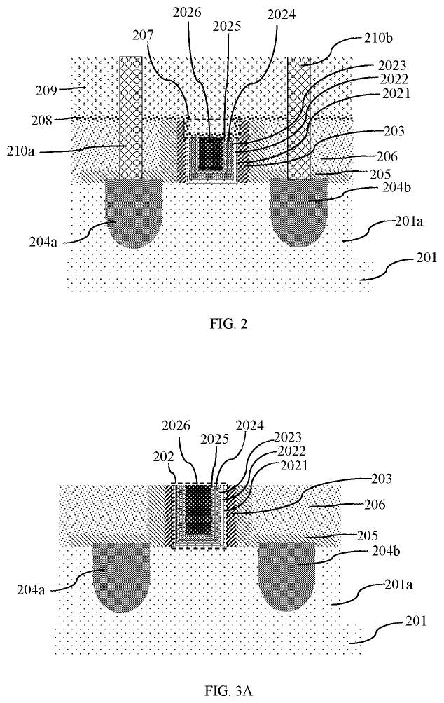

Referring to FIG. 2, which is a schematic structural diagram of a high dielectric-constant metal gate MOS transistor according to an embodiment of the present application, a zeroth interlayer film 206 and a gate structure are formed on the surface of a semiconductor substrate 201.

The gate structure is formed by stacking a gate dielectric layer and a metal gate, wherein the gate dielectric layer comprises a high dielectric-constant layer 2022. That is, the gate structure is a high dielectric-constant metal gate.

The top surface of the metal gate is lower than the top surface of the zeroth interlayer film 206. A first groove 207 is formed on the top surface of the metal gate. The edge top of the first groove 207 is flush with the top surface of the zeroth interlayer film 206.

A gate top plug formed by stacking a first barrier layer 208 and a first oxide layer is formed in the first groove 207. The first barrier layer 208 is arranged on the bottom surface and the side surfaces of the first groove 207, and the first oxide layer fully fills the first groove 207.

The first barrier layer 208 is made of a material that can prevent oxygen ions or fluorine ions from diffusing into the high dielectric-constant layer 2022 of the gate structure.

The first barrier layer 208 extends to the surface of the zeroth interlayer film 206 outside the first groove 207.

The material of the first barrier layer 208 is selected from one of SiN, SiON, SiC, SiCN, SiCBN, SiOBN, Al₂O₃, and ZrO₂, or the first barrier layer 208 is formed by stacking more than two layers each selected from one of SiN, SiON, SiC, SiCN, SiCBN, SiCOBN, Al₂O₃, and ZrO₂.

The semiconductor substrate 201 includes a silicon substrate.

The high dielectric-constant metal gate MOS transistor is a fin transistor; a fin 201a is formed on the semiconductor substrate 201, the fin 201a is made of the material of the semiconductor substrate 201, and the top surface and the side surfaces of the fin 201a are arranged on the surface of the semiconductor substrate 201 outside the fin 201a. The high dielectric-constant metal gate MOS transistor is formed on the fin 201a.

In a formation area of the gate structure, the gate structure covers the top surface and the side surfaces of the fin 201a. The structure in FIG. 2 is a cross sectional structure cut along the length direction of the fin 201a, so FIG. 2 only illustrates the gate structure on the top surface of the fin 201a.

A source area 204a and a drain area 204b are formed in the fin 201a on two sides of the gate structure. A first interlayer film 209 covers the surfaces of the zeroth interlayer film and the gate top plug. In order to improve the mobility of carriers in a channel area, an embedded epitaxial layer is formed in the source area 204a and the drain area 204b. If the high dielectric-constant metal gate MOS transistor is an N-type device, the embedded epitaxial layer contains SiP or SiC; and if the high dielectric-constant metal gate MOS transistor is a P-type device, the embedded epitaxial layer contains SiGe.

In the embodiment of the present application, the first oxide layer is directly composed of the first interlayer film 209 filling the first groove 207.

A zeroth metal active layer penetrating through the first interlayer film 209 and the zeroth interlayer film 206 is formed on the top of each of the source area 204a and the drain area 204b. The zeroth metal active layer on the top of the source area 204a is marked with a mark 210a, and the zeroth metal active layer on the top of the drain area 204b is marked with a mark 210b.

In the embodiment of the present application, the formation area of the gate structure is defined by a dummy gate structure, and the gate structure is formed in an area where the dummy gate structure is removed.

A sidewall 203 is formed on the side surfaces of the dummy gate structure by means of self-alignment. The heavily-doped source and drain implantation of the source area 204a and the drain area 204b is self-aligned with the side surfaces of the sidewall 203.

A contact etch stop layer (CESL) 205 covers the top surface of the dummy gate structure, the side surfaces of the sidewall, and the surface of the semiconductor substrate 201 outside the sidewall. The zeroth interlayer film 206 is formed on the upper surface of the contact etch stop layer 205. An etch-back or chemical mechanical planarization process is performed to remove the zeroth interlayer film 206 and the contact etch stop layer 205 on the top surface of the dummy gate structure and to make the top surfaces of the zeroth interlayer film 206 and the contact etch stop layer 205 outside the dummy gate structure flush with the top surface of the dummy gate structure. After the top surface of the dummy gate structure is exposed, a gate replacement process is performed. In the gate replacement process, the dummy gate structure is removed, and then gate structure is formed in the area where the dummy gate structure is removed.

In the embodiment of the present application, the gate dielectric layer of the gate structure includes an interface layer 2021, a high dielectric-constant layer 2022, and a bottom barrier metal (BBM) 2023 that are sequentially stacked up; and the metal gate of the gate structure includes a work function layer 2024, a top barrier metal (TBM) 2025, and a metal conductive material layer 2026 that are sequentially stacked up.

If the high dielectric-constant metal gate MOS transistor is an N-type device, the work function layer 2024 is an N-type work function layer; and if the high dielectric-constant metal gate MOS transistor is a P-type device, the work function layer 2024 is a P-type work function layer. If an N-type device and a P-type device are integrated together, in order to save the production cost, an N-type work function layer is superposed on the surface of a P-type work function layer in the P-type device.

The material of the interface layer 2021 includes silicon oxide.

The material of the high dielectric-constant layer 2022 includes one of silicon nitride, aluminum sesquioxide, tantalum pentoxide, yttrium oxide, hafnium silicate, hafnium dioxide, lanthanum oxide, zirconium dioxide, strontium titanate, and zirconium silicate.

The bottom barrier metal 2023 includes a stacked layer of a TiN layer and a TaN layer.

The material of the top barrier metal 2025 is TiN or a stacked layer of TiN and Ti.

The material of the N-type work function layer includes TiAl, TiAlC, TiALN; and the material of the P-type work function layer includes TiN.

In the embodiment of the present application, a contact is formed in a lead-out area of the gate structure. The cross sectional structure shown in FIG. 2 does not show the contact on the top of the gate structure. The contact on the top of the gate structure penetrates through the gate top plug.

Unlike a gate top plug of a high dielectric-constant metal gate MOS transistor that is formed by filling with a silicon nitride material in existing techniques, the gate top plug in the embodiment of the present application has a structure filled by stacking the first barrier layer and the first oxide layer into the first groove 207. In the stacked structure, the existence of the first barrier layer 207 can prevent oxygen ions or fluorine ions from diffusing into the high dielectric-constant layer 2022 of the gate structure, thereby reducing the threshold voltage mismatch of the device; and since the dielectric-constant of the first oxide layer is lower than that of silicon nitride, the gate-drain capacitance will be reduced, thereby improving the performance of the alternating current in the device.

In addition, the performance of filling the first oxide layer in the first groove 207 according to the embodiment of the present application is better than that of silicon nitride, because the voids from filling the first groove can be reduced and the filling quality is improved, and the requirement from the device process node shrinking can be satisfied. For example, when the process node is moved to less than 7 nm, the length of the gate is reduced to 20 nm, in which case voids are easily produced during filing the first groove 207 with silicon nitride. However, in the present application, the voids are reduced by filling the first groove 207 with the first barrier layer 208 and the first oxide layer.

Moreover, since the materials of the first oxide layer and the first interlayer film 209 in the embodiment of the present application both are oxide films, the first oxide layer can be directly composed of the first interlayer film 209 filling the first groove 207; therefore, in the present application, one chemical mechanical planarization process can be saved, thereby saving the cost. In the existing structure of filling the first groove 207 with silicon nitride, a number of voids remain in the first groove 207 after the chemical mechanical planarization process, thereby deteriorating the performance of the device. In addition to cost saving, in the embodiment of the present application, the performance of the device can be improved by reducing the voids.

Furthermore, since a contact on the top of the metal gate penetrates through the gate top plug and the voids of the gate top plug of the present application are reduced, etching of the opening of the contact causes no damage to the gate top plug, thereby further reducing the threshold voltage mismatch of the device and improving the stability of the threshold voltage of the device. However, in the existing gate top plug formed by filling with silicon nitride, the etching of the opening of the contact on the top of the metal gate causes damage to the gate top plug, thereby affecting the threshold voltage mismatch performance and threshold voltage stability of the device.

In the embodiment of the present application, the performance of the isolation between the gate structure and the zeroth metal active layer on the top of each of the source area 204a and the drain area 204b can be improved, thereby improving the product yield. For example, the yield of SRAMs or logic circuits adopting the high dielectric-constant metal gate MOS transistor of the embodiment of the present application can be improved.

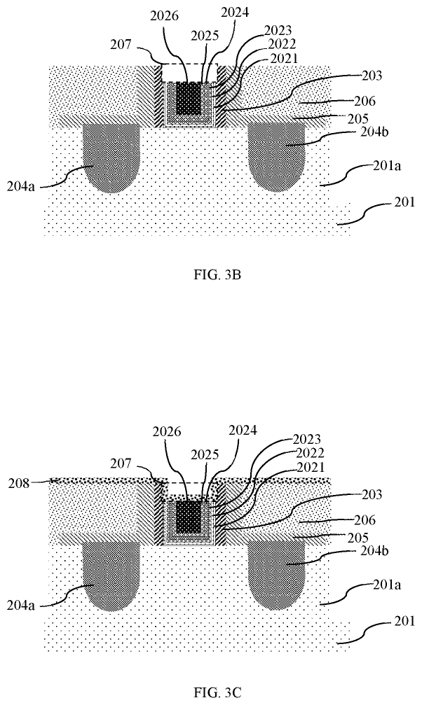

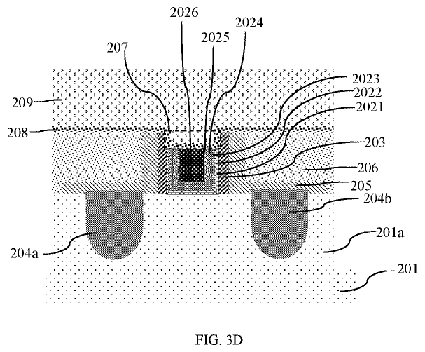

Referring to FIGS. 3A-3D, which are schematic device structures diagrams at steps of a method for manufacturing a high dielectric-constant metal gate MOS transistor in an embodiment of the present application. The method for manufacturing the high dielectric-constant metal gate MOS transistor according to the embodiment of the present application includes the following steps.

Step 1: referring to FIG. 2A, a zeroth interlayer film 206 and a gate structure are formed on the surface of a semiconductor substrate 201.

The gate structure is formed by stacking a gate dielectric layer and a metal gate, and the gate dielectric layer includes a high dielectric-constant layer 2022.

Chemical mechanical planarization is performed on the metal gate so that the top surface of the metal gate is flush with the top surface of the zeroth interlayer film 206.

In FIG. 3A, a formation area of the gate structure is shown in the dashed line box 202. The gate structure is generally formed by means of a gate last process. The gate last process is a common technique in this field and is briefly described as follows:

The gate structure formation area is defined by a dummy gate structure, and the gate structure is formed in an area where the dummy gate structure is removed.

The dummy gate structure is formed before the gate structure is formed, and the dummy gate structure is generally formed by stacking a gate oxide layer and a dummy polysilicon gate.

Next, sidewalls 203 are formed on the side surfaces of the dummy gate structure in the manner of self-alignment.

Next, a source area 204a and a drain area 204b are formed on the side surfaces of the sidewalls 203 of the dummy gate structure by means of implantation to form heavily-doped source and drain in the manner of self-alignment. In order to improve the mobility of carriers in a channel area, a step of forming an embedded epitaxial layer in both formation areas of the source area 204a and the drain area 204b is performed before implantating the heavily-doped source and drain areas. The step of forming the embedded epitaxial layer includes first forming a second groove in the semiconductor substrate 201 on both sides of the gate structure and then filling the second groove with an epitaxial layer to form the embedded epitaxial layer. If the high dielectric-constant metal gate MOS transistor is an N-type device, the embedded epitaxial layer contains SiP or SiC; and if the high dielectric-constant metal gate MOS transistor is a P-type device, the embedded epitaxial layer contains SiGe.

Next, a contact etch stop layer 205 is formed, wherein the contact etch stop layer 205 covers the top surface of the dummy gate structure, the side surfaces of the sidewalls, and the surface of the semiconductor substrate 201 outside the sidewalls.

Next, the zeroth interlayer film 206 is formed, wherein the zeroth interlayer film 206 covers the top surface of the contact etch stop layer 205.

Next, an etch-back or chemical mechanical planarization process is performed to remove the zeroth interlayer film 206 and the contact etch stop layer 205 on the top surface of the dummy gate structure and to make the top surfaces of the zeroth interlayer film 206 and the contact etch stop layer 205 outside the dummy gate structure flush with the top surface of the dummy gate structure. The top surface of the dummy gate structure is exposed.

Then, the dummy gate structure is removed.

Then, the gate structure is formed.

In the method of the embodiment of the present application, the gate dielectric layer of the gate structure includes an interface layer 2021, a high dielectric-constant layer 2022, and bottom barrier metal 2023 that are sequentially stacked up; and the metal gate of the gate structure includes a work function layer 2024, top barrier metal 2025, and a metal conductive material layer 2026 that are sequentially stacked up.

If the high dielectric-constant metal gate MOS transistor is an N-type device, the work function layer 2024 is an N-type work function layer; and if the high dielectric-constant metal gate MOS transistor is a P-type device, the work function layer 2024 is a P-type work function layer. If an N-type device and a P-type device are integrated together, in order to save the production cost, an N-type work function layer is superposed on the surface of a P-type work function layer in the P-type device; in this case, the P-type work function layer is first formed in the formation areas of the N-type device and the P-type device, then the N-type work function layer in the formation area of the N-type device is removed, and then the N-type work function layer is formed in the formation areas of both the N-type device and the P-type device. In this way, the N-type work function layer is superposed on the surface of the P-type work function layer in the formation area of the P-type device.

The material of the interface layer 2021 includes silicon oxide.

The material of the high dielectric-constant layer 2022 includes one of silicon nitride, aluminum sesquioxide, tantalum pentoxide, yttrium oxide, hafnium silicate, hafnium dioxide, lanthanum oxide, zirconium dioxide, strontium titanate, and zirconium silicate.

The bottom barrier metal 2023 includes a stacked layer of a titanium nitride (TiN) layer and a tantalum nitride (TaN) layer.

The material of the top barrier metal 2025 is TiN or a stacked layer of TiN and Ti.

The material of the N-type work function layer includes titanium aluminide (TiAl), titanium aluminium carbide (TiAlC), titanium aluminium nitride (TiALN); and the material of the P-type work function layer includes TiN.

In the method of the embodiment of the present application, the semiconductor substrate 201 includes a silicon substrate.

The high dielectric-constant metal gate MOS transistor is a fin transistor; a fin 201a is formed on the semiconductor substrate 201, the fin 201a is made of the material of the semiconductor substrate 201, and the top surface and the side surfaces of the fin 201a are arranged on the surface of the semiconductor substrate 201 outside the fin 201a.

The high dielectric-constant metal gate MOS transistor is formed on the fin 201a.

In the formation area of the gate structure, the gate structure covers the top surface and the side surfaces of the fin 201a.

The source area 204a and the drain area 204b are formed in the fin 201a on two sides of the gate structure.

Step 2: referring to FIG. 3B, the metal gate is etched back so that the top surface of the metal gate is lower than the top surface of the zeroth layer interlayer film 206, and a first groove 107 is formed on the top surface of the metal gate, wherein the top surface of the first groove 107 is flush with the top surface of the zeroth interlayer film 206.

Step 3: referring to FIG. 3C, a first barrier layer 208 is formed on the bottom surface and the side surfaces of the first groove 207, wherein the first barrier layer 208 is made of a material that can prevent oxygen ions or fluorine ions from diffusing into the high dielectric-constant layer 2022 of the gate structure.

The first barrier layer 208 extends to the surface of the zeroth interlayer film 206 outside the first groove 207.

The material of the first barrier layer is selected from one of SiN, SiON, SiC, SiCN, SiCBN, SiOBN, Al₂O₃, and ZrO₂, or the first barrier layer is formed by stacking more than two layers each selected from one of SiN, SiON, SiC, SiCN, SiCBN, SiCOBN, Al₂O₃, and ZrO₂.

Step 4: the first groove 207 is filled with a first oxide layer, and a gate top plug is formed by stacking the first barrier layer 208 and the first oxide layer.

The method further includes the following step:

A first interlayer film 209 is formed, wherein the first interlayer film 209 covers the surfaces of the zeroth interlayer film and the gate top plug.

In the method of the embodiment of the present application, the first oxide layer serves as a portion of the first interlayer film 209, the first oxide layer is directly composed of the first interlayer film 209 filling the first groove 207, and step 4 is merged with the step of forming the first interlayer film 209.

The method further includes the following step:

A zeroth metal layer is formed, wherein the zeroth metal layer includes a zeroth metal active layer, and the zeroth metal active layer penetrating through the first interlayer film 209 and the zeroth interlayer film 206 is formed on the top of each of the source area 204a and the drain area 204b.

Then, subsequent formation processes of an interlayer film and a contact are performed until all back-end-of-line (BEOL) processes are completed. The subsequent process is the same as the existing process and is not described in detail herein.

The present application is described in detail above via specific embodiments, but these embodiments are not intended to limit the present application. Without departing from the principle of the present application, those skilled in the art can still make many variations and improvements, which should also be considered to fall into the protection scope of the present application.

What is claimed is:

1. A high dielectric-constant metal gate MOS transistor, comprising
a semiconductor substrate;
a zeroth interlayer film and a gate structure formed on a surface of the semiconductor substrate; wherein the gate structure is formed by stacking a gate dielectric layer and a metal gate, wherein the gate dielectric layer comprises a high dielectric-constant layer;
a first groove formed on a top surface of the metal gate, wherein a top surface of the first groove is flush with a top surface of the zeroth interlayer film, wherein the top surface of the metal gate is lower than the top surface of the zeroth interlayer film; and
a gate top plug formed in the first groove, wherein the gate top plug comprises a first barrier layer and a first oxide layer stacked together, wherein the first barrier layer is arranged to be disposed on a bottom surface and side surfaces of the first groove, and wherein the first oxide layer is arranged to fill the first groove; and
wherein the first barrier layer is comprises a material capable of blocking oxygen ions or fluorine ions from diffusing into the high dielectric-constant layer of the gate structure.

2. The high dielectric-constant metal gate MOS transistor according to claim 1, wherein the first barrier layer extends to the top surface of the zeroth interlayer film outside the first groove.

3. The high dielectric-constant metal gate MOS transistor according to claim 1, wherein a material of the first barrier layer is selected from one of SiN, SiON, SiC, SiCN, SiCBN, SiOBN, Al₂O₃, and ZrO₂, or wherein the first barrier layer is formed by stacking more than two layers each selected from one of SiN, SiON, SiC, SiCN, SiCBN, SiCOBN, Al₂O₃, and ZrO₂.

4. The high dielectric-constant metal gate MOS transistor according to claim 1, wherein the semiconductor substrate comprises a silicon substrate.

5. The high dielectric-constant metal gate MOS transistor according to claim 2, wherein the high dielectric-constant metal gate MOS transistor is a fin transistor; wherein a fin is formed on the semiconductor substrate, wherein the fin comprises a material of the semiconductor substrate;
wherein a top surface and side surfaces of the fin are arranged on the surface of the semiconductor substrate outside the fin;
wherein the high dielectric-constant metal gate MOS transistor is formed on the fin;
wherein the gate structure covers the top surface and the side surfaces of the fin in a formation area of the gate structure; and
wherein a source area and a drain area are formed in the fin on two sides of the gate structure.

6. The high dielectric-constant metal gate MOS transistor according to claim 5, wherein a first interlayer film covers the top surface of the zeroth interlayer film and a top surface of the gate top plug.

7. The high dielectric-constant metal gate MOS transistor according to claim 6, wherein the first oxide layer comprises the first interlayer film that fills the first groove.

8. The high dielectric-constant metal gate MOS transistor according to claim 6, wherein a zeroth metal active layer penetrates through the first interlayer film and the zeroth interlayer film and stops on a top surface of the source area and a top surface of the drain area.

9. A method for manufacturing a high dielectric-constant metal gate MOS transistor, comprising following steps:
step 1: forming a zeroth interlayer film and a gate structure on a surface of a semiconductor substrate,
wherein the gate structure is formed by stacking a gate dielectric layer and a metal gate, wherein the gate dielectric layer comprises a high dielectric-constant layer; and
performing chemical mechanical planarization on the metal gate, wherein the top surface of the metal gate is configured to be flush with the top surface of the zeroth interlayer film;
step 2: etching back the metal gate, wherein the top surface of the metal gate is arranged to be lower than the top surface of the zeroth interlayer film; and
forming a first groove on the top surface of the metal gate, wherein a top edge of the first groove is arranged to be flush with the top surface of the zeroth interlayer film;
step 3: forming a first barrier layer on a bottom surface and side surfaces of the first groove, wherein the first barrier layer comprises a material which stops oxygen ions or fluorine ions from diffusing into the high dielectric-constant layer of the gate structure; and
Step 4: filling the first groove with a first oxide layer, and forming a gate top plug by stacking the first barrier layer and the first oxide layer.

10. The method for manufacturing the high dielectric-constant metal gate MOS transistor according to claim 9, wherein the first barrier layer extends to the top surface of the zeroth interlayer film outside the first groove.

11. The method for manufacturing the high dielectric-constant metal gate MOS transistor according to claim 9, wherein a material of the first barrier layer is selected from one of SiN, SiON, SiC, SiCN, SiCBN, SiOBN, Al₂O₃, and ZrO₂, or wherein the first barrier layer is formed by stacking more than two layers each selected from one of SiN, SiON, SiC, SiCN, SiCBN, SiCOBN, Al₂O₃, and ZrO₂.

12. The method for manufacturing the high dielectric-constant metal gate MOS transistor according to claim 9, wherein the semiconductor substrate comprises a silicon substrate.

13. The method for manufacturing the high dielectric-constant metal gate MOS transistor according to claim 10, wherein the high dielectric-constant metal gate MOS transistor is a fin transistor; wherein a fin is formed on the semiconductor substrate, wherein the fin comprises a material of the semiconductor substrate, and wherein a top surface and side surfaces of the fin are arranged on a surface of the semiconductor substrate outside the fin;
wherein the high dielectric-constant metal gate MOS transistor is formed on the fin;
wherein in a formation area of the gate structure, the gate structure covers the top surface and the side surfaces of the fin; and
wherein a source area and a drain area are formed in the fin on two sides of the gate structure.

14. The method for manufacturing the high dielectric-constant metal gate MOS transistor according to claim 13, further comprising a step of:
forming a first interlayer film, wherein the first interlayer film covers the top surface of the zeroth interlayer film and a top surface of the gate top plug.

15. The method for manufacturing the high dielectric-constant metal gate MOS transistor according to claim 14, wherein the first oxide layer serves as a portion of the first interlayer film, the first oxide layer is directly composed of the first interlayer film filling the first groove, and step 4 is merged with the step of forming the first interlayer film.

16. The method for manufacturing the high dielectric-constant metal gate MOS transistor according to claim 14, further comprising a step of:
forming a zeroth metal layer, wherein the zeroth metal layer comprises a zeroth metal active layer, wherein the zeroth metal active layer penetrates through the first interlayer film and the zeroth interlayer film and stops on a top surface of the source area and a top surface of the drain area.
